(19) United States
(12) Patent Application Publication
(10) Pub. No.: US 2024/0290868 A1
(43) Pub. Date: Aug. 29, 2024

(54) SEMICONDUCTOR DEVICE

(71) Applicant: Samsung Electronics Co., Ltd., Suwon-si (KR)

(72) Inventors: Taejin PARK, Suwon-si (KR); Bongsoo KIM, Suwon-si (KR); Huijung KIM, Suwon-si (KR)

(73) Assignee: Samsung Electronics Co., Ltd., Suwon-si (KR)

(21) Appl. No.: 18/404,607

(22) Filed: Jan. 4, 2024

(30) Foreign Application Priority Data
Jan. 10, 2023 (KR) 10-2023-0003410

(51) Int. Cl. H01L 29/66; H01L 29/06; H10B 12/00

(52) U.S. Cl. CPC H01L 29/6656; H01L 29/0649; H10B 12/315

(57) ABSTRACT

A semiconductor device includes a first structure including a first impurity region, a second impurity region, and an isolation region, a second structure on the first structure and including a contact opening penetrating through the second structure and exposing the first impurity region, a pattern structure including a contact portion connected to the first impurity region in the contact opening, and a line portion on the contact portion and the second structure, and a spacer structure between a side surface of the contact opening and the contact portion. The spacer structure includes a first spacer layer on the side surface of the contact opening, and a second spacer layer between the first spacer layer and the contact portion. A lower end of the second spacer layer is at a higher level than a lower surface of the contact portion.

### CROSS-REFERENCE TO RELATED APPLICATION(S)

This application claims benefit of priority to Korean Patent Application No. 10-2023-0003410 filed on Jan. 10, 2023 in the Korean Intellectual Property Office, the disclosure of which is incorporated herein by reference in its entirety.

### BACKGROUND

Example embodiments relate to semiconductor devices and/or methods of manufacturing the same.

Research has been conducted to reduce sizes of elements included in a semiconductor device and to improve performance thereof. With a reduction in the sizes of the elements included in the semiconductor device, the technology for forming a contact has become increasingly complex.

### SUMMARY

Some example embodiments provide reliable semiconductor devices.

According to an example embodiment, a semiconductor device may include a first structure having a first impurity region, a second impurity region, and an isolation region, a second structure on the first structure, the second structure including a contact opening penetrating therethrough and exposing the first impurity region, a pattern structure including a contact portion connected to the first impurity region in the contact opening, and a line portion on the contact portion and the second structure, and a spacer structure between a side surface of the contact opening and the contact portion. The spacer structure may include a first spacer layer on the side surface of the contact opening, and a second spacer layer between the first spacer layer and the contact portion. A lower end of the second spacer layer may be at a level higher than that of a lower surface of the contact portion. The contact portion of the pattern structure includes a first contact region connected to the first impurity region, and a first extension portion protruding from the first contact region and extending between the lower surface of the second spacer layer and a bottom surface of the contact opening.

According to an example embodiment, a semiconductor device may include a first structure having a first impurity region, a second impurity region, and an isolation region, a second structure including a pad pattern connected to the second impurity region, an insulating isolation pattern having a side surface in contact with a side surface of the pad pattern, and an insulating buffer pattern on the pad pattern and the insulating isolation pattern, the second structure including a contact opening penetrating therethrough and exposing an upper surface of the first impurity region and a portion of the isolation region, a pattern structure including a contact portion in the contact opening and a line portion on the contact portion and the second structure, a contact spacer structure between a side boundary of the contact opening defined by the second structure and the contact portion, and a contact structure connected to an upper surface of the pad pattern, the contact structure extending upwardly. The contact spacer structure may include a first spacer layer on the side boundary of the contact opening, and a second spacer layer between the first spacer layer and the contact portion. The second spacer layer may have a first side surface in contact with the first spacer layer and a second side surface opposing the first side surface. A lower end of the second spacer layer may be at a level higher than that of a lower end of the first spacer layer. A lower end of the second side surface of the second spacer layer may not vertically overlap the first spacer layer.

According to an example embodiment, a semiconductor device may include a first structure, a second structure on the first structure, the second structure including a contact opening penetrating therethrough, a pattern structure including a contact portion in the contact opening, and a line portion on the contact portion and the second structure, and a contact spacer structure between a side boundary of the contact opening defined by the second structure and the contact portion. The first structure may include a substrate, a first active region and a second active region on the substrate, an isolation region on side surfaces of the first and second active regions, a first impurity region in an upper region of the first active region and a second impurity region in an upper region of the second active region, a gate trench traversing the first and second active regions and extending into the isolation region, and a gate structure in the gate trench. The gate structure may include a gate dielectric layer covering an inner wall of the gate trench, a gate electrode partially filling the gate trench on the gate dielectric layer, and a gate capping pattern on the gate electrode in the gate trench. The gate electrode may have a linear shape extending in a first horizontal direction. The line portion may have a linear shape extending in a second horizontal direction, perpendicular to the first horizontal direction. The second structure may include a pad pattern connected to the second active region, an insulating isolation pattern in contact with side surfaces of the pad pattern, and an insulating buffer pattern on the pad pattern and the insulating isolation pattern. The contact opening may expose the first impurity region, the isolation region adjacent to the first impurity region, and the gate capping pattern adjacent to the first impurity region. The contact spacer structure may include a first spacer layer on the side boundary of the contact opening and a second spacer layer between the first spacer layer and the contact portion. A material of the first spacer layer may be different from a material of the second spacer layer. A lower end of the first spacer layer may be at a level lower than that of a lower end of the second spacer layer. Each of the first and second spacer layers may have a ring shape in plan view.

### BRIEF DESCRIPTION OF DRAWINGS

The above and other aspects, features, and advantages of the present inventive concepts will be more clearly understood from the following detailed description, taken in conjunction with the accompanying drawings, in which:

FIGS. 1, 2A, 2B, 3A, and 3B are schematic diagrams illustrating a semiconductor device according to an example embodiment of the present inventive concepts;

FIG. 4 is a schematic partially enlarged view of a modification of a semiconductor device according to an example embodiment of the present inventive concepts;

FIG. 5 is a schematic partially enlarged view of a modification of a semiconductor device according to an example embodiment of the present inventive concepts;

FIG. 6 is a schematic partially enlarged view of a modification of a semiconductor device according to an example embodiment of the present inventive concepts;

FIG. 7 is a schematic partially enlarged view of a modification of a semiconductor device according to an example embodiment of the present inventive concepts;

FIG. 8 is a schematic partially enlarged view of a modification of a semiconductor device according to an example embodiment of the present inventive concepts;

FIG. 9 is a schematic partially enlarged view of a modification of a semiconductor device according to an example embodiment of the present inventive concepts;

FIG. 10 is a schematic partially enlarged view of a modification of a semiconductor device according to an example embodiment of the present inventive concepts;

FIG. 11 is a schematic partially enlarged view of a modification of a semiconductor device according to an example embodiment of the present inventive concepts;

FIG. 12 is a process flowchart illustrating an example of a method of forming a semiconductor device according to an example embodiment of the present inventive concepts; and

FIGS. 13A to 16B are partially enlarged views of a method of forming a semiconductor device according to an example embodiment of the present inventive concepts.

### DETAILED DESCRIPTION

Hereinafter, terms such as “upper”“intermediate” and “lower” may be replaced with other terms, for example, “first,”“second,” and “third” to describe elements of the specification. Terms such as “first,”“second,” and “third” may be used to describe different elements, but the elements are not limited by the terms, and a “first element” may be referred to as a “second element.”

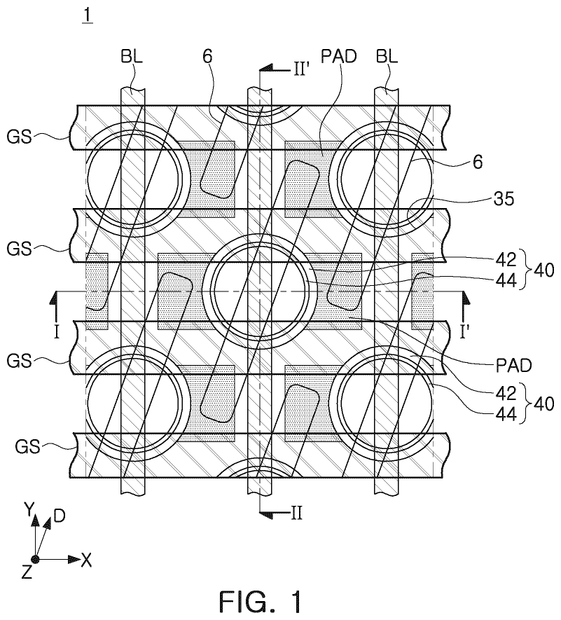

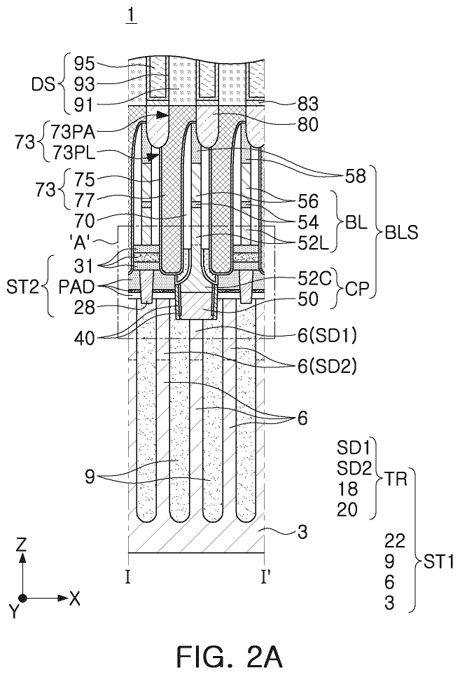

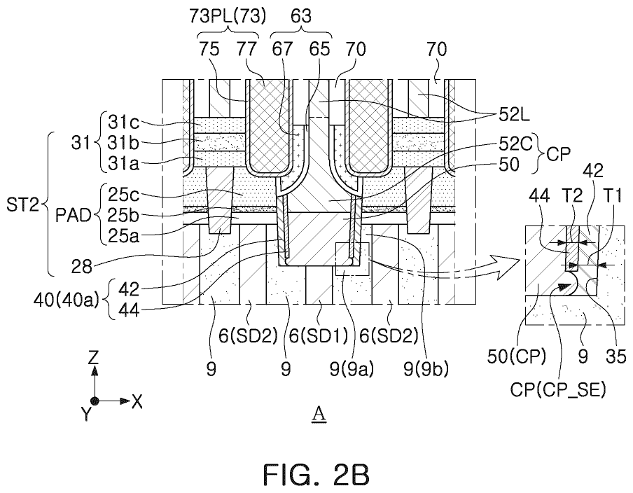

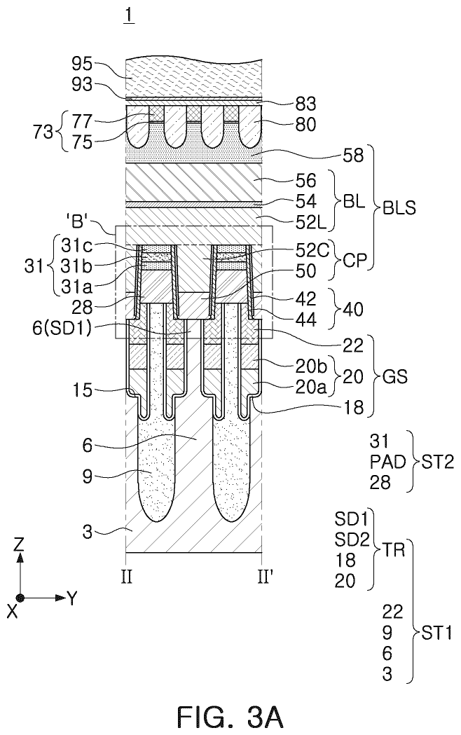

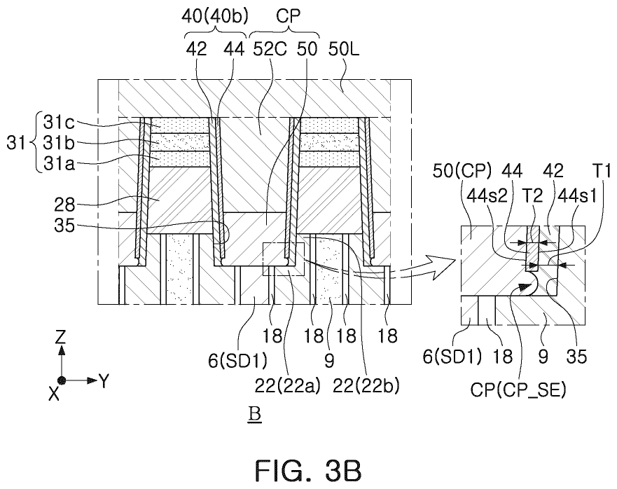

A semiconductor device according to an example embodiment of the present inventive concepts will be described with reference to FIGS. 1, 2A, 2B, 3A, and 3B. In FIGS. 1, 2A, 2B, 3A, and 3B, FIG. 1 is a schematic plan view of a semiconductor device according to an example embodiment of the present inventive concepts, FIG. 2A is a schematic cross-sectional view of a region taken along line I-I′ of FIG. 1, FIG. 2B is a partially enlarged view of a region indicated by “A” of FIG. 2A, FIG. 3A is a schematic cross-sectional view of a region taken along line II-II' of FIG. 1, and FIG. 3B is a partially enlarged view of a region indicated by “B” of FIG. 3A.

Referring to FIGS. 1, 2A, 2B, 3A, and 3B, a semiconductor device 1 according to an example embodiment may include a first structure ST1, a second structure ST2 on the first structure ST1, a contact opening 35 penetrating through the second structure ST2 and extending into the first structure ST1, a pattern structure BLS including a contact portion CP in the contact opening 35 and a line portion BL on the contact portion CP and the second structure ST2, and a first contact spacer structure 40 between a side surface of the contact opening 35 (e.g., a side boundary of the contact opening defined by the second structure ST2) and the contact portion CP.

The first structure ST1 may include first impurity regions SD1, second impurity regions SD2, and an isolation region 9. The first structure ST1 may further include a substrate 3 and active regions 6 on the substrate 3.

The substrate 3 may be a semiconductor substrate. For example, the substrate 3 may include a Group IV semiconductor, a Group III-V compound semiconductor, or a Group II-VI compound semiconductor. For example, the Group IV semiconductor may include silicon, germanium, or silicon-germanium. For example, the substrate 3 may include a silicon material, for example, a single crystal silicon material. The substrate 3 may be a silicon substrate, a silicon on insulator (SOI) substrate, a germanium substrate, a germanium on insulator (GOI) substrate, a silicon-germanium substrate, or a substrate including an epitaxial layer.

The isolation region 9 may define the active regions 6 on the substrate 3. For example, the isolation region 9 may be disposed on side surfaces of the active regions 6. The isolation region 9 may be a trench device isolation layer. The isolation region 9 may include an insulating material such as silicon oxide and/or silicon nitride.

Each of the active regions 6 may have a pin shape protruding from the substrate 3 in a vertical direction Z. The active regions 6 may be formed of a material the same as that of the substrate 3, for example, silicon. For example, the active regions 6 may include monocrystalline silicon. The vertical direction Z may be a direction, perpendicular to an upper surface of the substrate 3. The active regions 6 may be parallel to each other.

The first structure ST1 may further include gate trenches 15, traversing the active regions 6 and extending into the isolation region 9, and gate structures GS in the gate trenches 15. The gate structures GS may be parallel to each other.

In plan view, each of the gate structures GS may have a linear shape extending in a first horizontal direction X. In plan view, each of the active regions 6 may have a bar shape or linear shape extending in an oblique direction D. The oblique direction D may be a direction, intersecting the first horizontal direction X while forming an obtuse angle or an acute angle.

Each of the gate structures GS includes a gate dielectric layer 18, covering an inner wall of the gate trench 15, and a gate electrode 20, which partially fills the gate trench 15 on the gate dielectric layer 18, and a gate capping pattern 22, which fills a remaining portion of the gate trench 15 on the gate electrode 20.

The gate dielectric layer 18 may include at least one of silicon oxide and a high-κ dielectric. The high-κ dielectric may be a dielectric having a dielectric constant higher than that of silicon oxide. The gate electrode 20 may include doped polysilicon, a metal, a conductive metal nitride, a metal-semiconductor compound, a conductive metal oxide, graphene, carbon nanotubes, or combinations thereof. For example, the gate electrode 20 may be formed of doped polysilicon, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrOₓ, RuOₓ, graphene, carbon nanotubes, or combinations thereof, but the present inventive concepts are not limited thereto. The gate electrode 20 may include a single layer or multiple layers formed of the above-described materials. For example, the gate electrode 20 may include a first electrode layer 20a that may be formed of a metal material and a second electrode layer 20b that may be formed of doped polysilicon on the first electrode layer 20a. The gate capping pattern 22 may include an insulating material, for example, silicon nitride.

The first impurity regions SD1 may be first source/drain regions, and the second impurity regions SD2 may be second source/drain regions.

The first and second impurity regions SD1 and SD2, the gate electrode 20, and the gate dielectric layer 18 may be included in a transistor TR. The transistor TR may be a cell transistor in a memory such as a DRAM.

In the first structure ST1, the first impurity regions SD1 and the second impurity regions SD2 may be disposed in the active regions 6. The first and second impurity regions SD1 and SD2 may be disposed in upper regions of the active regions 6.

In some example embodiments, the first and second impurity regions SD1 and SD2 may be referred to as the upper regions of the active regions 6. In addition, the first and second impurity regions SD1 and SD2 may be referred to as first and second source/drain regions.

One active region 6, among the active regions 6, may intersect a pair of adjacent gate structures GS among the gate structures GS. In plan view, when viewed relative to one active region 6 among the active regions 6, one first impurity region SD1 may be disposed in a middle portion of the active region 6, and the second impurity regions SD2 may be disposed at both end portions of the active region 6. The first and second impurity regions SD1 and SD2 may be adjacent to the gate capping patterns 22.

The second structure ST2 may include an insulating buffer pattern 31. The insulating buffer pattern 31 may include at least one insulating layer. For example, the insulating buffer pattern 31 may include a first buffer layer 31a, a second buffer layer 31b, and a third buffer layer 31c sequentially stacked. The first buffer layer 31a may include silicon nitride, the second buffer layer 31b may include silicon oxide, and the third buffer layer 31c may include silicon nitride.

The second structure ST2 may further include pad patterns PAD and an insulating isolation pattern 28.

The pad patterns PAD may be spaced apart from each other. The pad patterns PAD may be on the second impurity regions SD2 and connected to the second impurity regions SD2, which are spaced apart from each other, respectively. For example, one pad pattern PAD may be electrically connected to one second impurity region SD2 by being in contact with the one second impurity region SD2. The one pad pattern PAD may be in contact with an upper surface of the second impurity region SD2 and electrically connected thereto, and thus may cover a portion of an upper surface of the isolation region 9, adjacent to the second impurity region SD2.

Each of the pad patterns PAD may include at least one conductive layer. Each of the pad patterns PAD may include doped polysilicon, a metal, a conductive metal nitride, a metal-semiconductor compound, a conductive metal oxide, graphene, carbon nanotubes, or combinations thereof. For example, each of the pad patterns PAD may be formed of doped polysilicon, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrOₓ, RuOₓ, graphene, carbon nanotubes, or combinations thereof, but the present inventive concepts are not limited thereto. Each of the pad patterns PAD may include a single layer or multiple layers formed of the above-described materials. For example, each of the pad patterns PAD may include a first pad layer 25a, a second pad layer 25b, and a third pad layer 25c sequentially stacked. The first pad layer 25a may be electrically connected to the second impurity region SD2 while being in contact with the second impurity region SD2. The first pad layer 25a may include doped silicon, the second pad layer 25b may include TiSiN or a metal-semiconductor compound, and the third pad layer 25c may include a metal such as W or the like.

The insulating isolation pattern 28 may include an insulating material such as silicon nitride. The insulating isolation pattern 28 and the pad patterns PAD may have side surfaces in contact with each other. For example, a side surface of the insulating isolation pattern 28 may be in contact with side surfaces of the pad patterns PAD. An upper surface of the insulating isolation pattern 28 may be coplanar with upper surfaces of the pad patterns PAD. The upper surface of the insulating isolation pattern 28 may be disposed at a level the same as or substantially similar to that of the upper surfaces of the pad patterns PAD. A lower surface of the insulating isolation pattern 28 may be disposed at a level lower than that of lower surfaces of the pad patterns PAD. The insulating isolation pattern 28 may pass between the pad patterns PAD and extend into the isolation region 9. The insulating isolation pattern 28 may cover a portion of the gate structure GS, adjacent to the isolation region 9. For example, the insulating isolation pattern 28 may cover an upper surface of a portion of the gate capping pattern 22 and an upper end of a portion of the gate dielectric layer 18.

A plurality of contact openings 35 may be disposed to expose the first impurity regions SD1, respectively. Hereinafter, for easier understanding, one contact opening 35 will be mainly described.

The contact opening 35 may pass through the second structure ST2 and extend into the first structure ST1 to expose the first impurity region SD1. In plan view, the contact opening 35 may have a circular shape or an elliptical shape.

As illustrated in FIGS. 2A and 2B, in a cross-sectional structure in which the contact portion CP and the line portion BL are cut in the first horizontal direction X, the contact opening 35 may pass through the second structure ST2 and extend downwardly while exposing the side surfaces of the pad patterns PAD, thereby exposing the first impurity region SD1. Here, an upper surface of the first impurity region SD1 may be disposed at a level lower than that of the upper surface of the second impurity region SD2, and the contact opening 35 may expose a portion of the isolation region 9, adjacent to the first impurity region SD1.

As illustrated in FIGS. 3A and 3B, in the cross-sectional structure in which the contact portion CP and the line portion BL are cut in a second horizontal direction Y, the contact opening 35 may pass through the second structure ST2 and extend downwardly while exposing the side surface of the insulating isolation pattern 28 and a side surface of the insulating buffer pattern 31, thereby exposing the first impurity region SD1. Here, the contact opening 35 may expose a portion of the gate capping pattern 22 and a portion of the gate dielectric layer 18, adjacent to the first impurity region SD1. The second horizontal direction Y may be a direction, perpendicular to the first horizontal direction X.

In the pattern structure BLS including the contact portion CP and the line portion BL, the contact portion CP may be disposed in the contact opening 35, and may be connected to the first impurity region SD1 exposed by the contact opening 35. The line portion BL may be disposed on the contact portion CP and the second structure ST2. The line portion BL may have a linear shape extending in the second horizontal direction Y.

The contact portion CP may be in contact with an upper surface of the first impurity region SD1 exposed by the contact opening 35, a portion of the gate capping pattern 22 adjacent to the first impurity region SD1, and a portion of the gate dielectric layer 18. The upper surface of the first impurity region SD1 exposed by the contact opening 35, an upper surface of the portion of the gate capping pattern 22 adjacent to the first impurity region SD1 exposed by the contact opening 35, and an upper surface of the portion of the gate dielectric layer 18 in contact with the contact portion CP may be coplanar with each other.

The gate capping pattern 22 may include a first capping region 22a vertically overlapping the contact portion CP and a second capping region 22b vertically overlapping the second structure ST2 (and not vertically overlapping the contact portion CP). An upper surface of the second capping region 22b of the gate capping pattern 22 may be disposed at a level higher than that of an upper surface of the first capping region 22a of the gate capping pattern 22. The contact portion CP may cover the upper surface of the first impurity region SD1 and the upper surface of the first capping region 22a of the gate capping pattern 22.

The isolation region 9 may include a first isolation region 9a vertically overlapping the contact portion CP and a second isolation region 9b vertically overlapping the second structure ST2 (and not vertically overlapping the contact portion CP). For example, the second isolation region 9b may be adjacent to the second impurity region SD2, and the pad pattern PAD may cover the second impurity region SD2 and the second isolation region 9b.

In the isolation region 9, an upper surface of the second isolation region 9b may be disposed at a level higher than an upper surface of the first isolation region 9a. The contact portion CP may cover the upper surface of the first impurity region SD1 and the upper surface of the first isolation region 9a. The upper surface of the first isolation region 9a and the upper surface of the first impurity region SD1 may be coplanar with each other.

The pattern structure BLS may include at least one material layer. For example, the pattern structure BLS may include doped silicon, doped germanium, doped silicon-germanium, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrOₓ, RuOₓ, graphene, carbon nanotubes, or combinations thereof, but the present inventive concepts are not limited. The pattern structure BLS may include a single material layer or multiple material layers formed of the above-described materials. For example, the pattern structure BLS may include a doped silicon layer, connected to the first impurity region SD1, and at least one conductive layer on the doped silicon layer. The doped silicon layer and the at least one conductive layer may be included in the contact portion CP and the line portion BL of the pattern structure BLS.

In the pattern structure BLS, the contact portion CP includes a first material layer 50, connected to the first impurity region SD1, and a second material layer 52C in contact with the first material layer 50 on the first material layer 50. The first material layer 50 may include at least one of a silicon layer, a germanium layer, and a silicon-germanium layer. For example, the first material layer 50 may be a doped silicon layer. The first material layer 50 may be a silicon layer having an N-type conductivity. The first material layer 50 may be a doped polysilicon layer or a doped epitaxial layer formed by an epitaxial growth process. The first material layer 50 may be a polysilicon layer having an N-type conductivity or an epitaxial silicon layer having an N-type conductivity. The second material layer 52C may be formed of doped polysilicon, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrOₓ, RuOₓ, graphene, carbon nanotubes, or combinations thereof, but the present inventive concepts are not limited thereto.

In the pattern structure BLS, the line portion BL may be connected to and aligned with the contact portion CP. The line portion BL may include a third material layer 52L, a fourth material layer 54 on the third material layer 52L, and a fifth material layer 56 on the fourth material layer 54. The third material layer 52L may include a material the same as that of the second material layer 52C. The third material layer 52L may be formed to continuously extend from the second material layer 52C. Accordingly, the second and third material layers 52C and 52L may be integrally formed or may be a single material layer. The fourth material layer 54 may include a conductive material different from that of the third material layer 52L. The fifth material layer 56 may include a conductive material different from that of the fourth material layer 54.

The pattern structure BLS may further include an insulating capping portion 58 aligned with the line portion BL on the line portion BL. The insulating capping portion 58 may include an insulating material such as silicon nitride. The insulating capping portion 58 may be referred to as a bit line capping portion or a bit line capping pattern.

A plurality of pattern structures BLS may be disposed. The line portions BL of the pattern structures BLS may be parallel to each other.

In some example embodiments, the gate electrodes 20 may be word lines of a memory such as a DRAM or the like, the line portions BL may be bit lines of a memory such as a DRAM or the like, and the contact portions CP may be contact plugs electrically connecting the first impurity regions SD1 and the bit lines BL to each other.

The first contact spacer structure 40 between a side surface of the contact opening 35 and the contact portion CP may be formed of an insulating material. The first contact spacer structure 40 between the side surface of the contact opening 35 and the contact portion CP may include a first spacer layer 42 and a second spacer layer 44. The first and second spacer layers 42 and 44 may include different insulating materials. The first spacer layer 42 may be disposed on the side surface of the contact opening 35. The second spacer layer 44 may be disposed between the first spacer layer 42 and the contact portion CP. A material of the first spacer layer 42 may be different from that of the second spacer layer 44. The first spacer layer 42 and the second spacer layer 44 may be formed of insulating materials having etch selectivity with respect to each other. For example, the first spacer layer 42 may be an oxide layer, and the second spacer layer 44 may be a SiOC material layer. The first spacer layer 42 may include silicon oxide, but example embodiments are not limited thereto. For example, when the second spacer layer 44 is a SiOC material layer, the first spacer layer 42 may be a silicon oxide layer, a low-κ dielectric layer, or a high-κ dielectric layer. Here, a low-κ dielectric may be a dielectric having a dielectric constant lower than that of silicon oxide, and a high-κ dielectric may be a dielectric having a dielectric constant higher than that of silicon oxide.

A lower surface of the second spacer layer 44 may be disposed at a level higher than a lower surface of the contact portion CP. The lower surface of the second spacer layer 44 may be disposed at a level higher than a lower end of the first spacer layer 42.

A thickness T2 of the second spacer layer 44 may be equal to or less than a thickness T1 of the first spacer layer 42. For example, the thickness T2 of the second spacer layer 44 may be less than the thickness T1 of the first spacer layer 42.

In plan view, the first contact spacer structure 40 may have a ring shape surrounding the first impurity region SD1. In plan view, each of the first and second spacer layers 42 and 44 may have a ring shape.

The first contact spacer structure 40 may be in contact with the isolation region 9 and the gate structure GS. The first contact spacer structure 40 may be in contact with the gate capping pattern 22 of the gate structure GS.

The contact portion CP of the pattern structure BLS may include a contact region, connected to the first impurity region SD1, and a first extension portion CP_SE extending between the lower surface of the second spacer layer 44 and a bottom surface of the contact opening 35 from the contact region. The first extension portion CP_SE of the contact portion CP may vertically overlap the second spacer layer 44. The first extension portion CP_SE of the contact portion CP may be convex in a direction toward the first spacer layer 42.

The second spacer layer 44 may have a first side surface 44s1 opposing the side surface of the contact opening 35 and a second side surface 44s2 opposing the first side surface 44s1. The first side surface 44s1 of the second spacer layer 44 may be in contact with the first spacer layer 42. The contact portion CP may be in contact with the second side surface 44s2 of the second spacer layer 44 and the lower surface of the second spacer layer 44.

A lower end of the second spacer layer 44 may be disposed at a level higher than that of the lower end of the first spacer layer 42, and a lower end of the second side surface 44s2 of the second spacer layer 44 may not vertically overlap the first spacer layer 42.

The first contact spacer structure 40 may include a first spacer region 40a not vertically overlapping the line portion BL and a second spacer region 40b vertically overlapping the line portion BL. The first spacer region 40a may be in contact with a side surface of the pad pattern PAD and a portion of a side surface of the isolation region 9 below the pad pattern PAD. The first spacer region 40a may be in contact with the side surface of the pad pattern PAD and extend downwardly to be in contact with the isolation region 9. The second spacer region 40b may be in contact with the side surface of the insulating isolation pattern 28 and the side surface of the insulating buffer pattern 31.

As illustrated in FIGS. 2A and 2B, in a cross-sectional structure in which the contact portion CP and the line portion BL are cut in the first horizontal direction X, the first contact spacer structure 40 may be in contact with the side surface of the pad pattern PAD and a side surface of the contact portion CP between the pad pattern PAD and the contact portion CP.

As illustrated in FIGS. 3A and 3B, in a cross-sectional structure in which the contact portion CP and the line portion BL are cut in the second horizontal direction Y, the first contact spacer structure 40 may be in contact with a side surface of the second structure ST2 and the side surface of the contact portion CP between the side surface of the second structure ST2 and the side surface of the contact portion CP. Here, the side surface of the second structure ST2 may be the side surface of the insulating isolation pattern 28 and the side surface of the insulating buffer pattern 31.

The semiconductor device 1 may further include a second contact spacer structure 63 and a line spacer 70. The line spacer 70 may be disposed on a side surface of the line portion BL. In the contact opening 35, the second contact spacer structure 63 may cover at least a portion of the side surface of the contact portion CP. In the contact opening 35, the second contact spacer structure 63 may cover an upper surface of the first contact spacer structure 40. In the first horizontal direction X, the second contact spacer structure 63 may be thicker than the first contact spacer structure 40.

The second contact spacer structure 63 may be disposed below the line spacer 70. The second contact spacer structure 63 may include an insulating liner 65 and a spacer pattern 67. In the second contact spacer structure 63, the insulating liner 65 may cover a side surface and a lower portion of the spacer pattern 67. In the second contact spacer structure 63, the insulating liner 65 and the spacer pattern 67 may be formed of different insulating materials. For example, the spacer pattern 67 may include silicon nitride, and the insulating liner 65 may include silicon oxide.

The line spacer 70 may include at least one layer. For example, the line spacer 70 may include at least one of silicon oxide, silicon nitride, silicon oxynitride, silicon carbon nitride (SiCN), and silicon oxygen carbon nitride (SiOCN). The line spacer 70 may further include an air gap. For example, the line spacer 70 may include an inner spacer, an outer spacer, and an air gap between the inner spacer and the outer spacer. Here, at least one of the inner spacer and the outer spacer of the line spacer 70 may include at least one of silicon oxide, silicon nitride, silicon oxynitride, silicon carbon nitride (SiCN), and silicon oxygen carbon nitride (SiOCN).

The semiconductor device 1 may further include a contact structure 73, an upper insulating isolation pattern 80, and a data storage structure DS.

The contact structure 73 may be electrically connected to the pad pattern PAD while being in contact with the pad pattern PAD, and may extend upwardly on the pad pattern PAD. The contact structure 73 may pass through the insulating buffer pattern 31 and may be extend to a level higher than that of an upper surface of the line portion BL from a region thereof in contact with the pad pattern PAD. The contact structure 73 may be disposed between the line portions BL adjacent to each other, among the pattern structures BLS adjacent to each other, may extend downwardly to be in contact with the pad pattern PAD, and may vertically overlap one insulating capping portion 58 among the insulating capping portions 58 of the pattern structures BLS.

The contact structure 73 may be disposed at a level the same as that of the pattern structure BLS, and may include a plug portion 73PL, which is electrically connected to the pad pattern PAD while being in contact with the pad pattern PAD, and a pad portion 73PA disposed at a level higher than that of the pattern structure BLS. The pad portion 73PA may be in contact with at least a portion of an upper surface of one insulating capping portion 58, among the capping portions 58 of the pattern structures BLS adjacent to each other, while vertically overlapping the at least a portion of the upper surface of the one insulating capping portion 58.

A lower surface of the second contact spacer structure 63 may be disposed at a level lower than that of a lower surface of the contact structure 73. The second contact spacer structure 63 may serve to block or prevent an electrical short-circuit between the contact structure 73 and the contact portion CP.

The upper insulating isolation pattern 80 may define a side surface of the pad portion 73PA, and a portion thereof may extend into the insulating capping portion 58. The upper insulating isolation pattern 80 may be in contact with the side surface of the pad portion 73PA. The upper insulating isolation pattern 80 may have an upper surface coplanar with an upper surface of the pad portion 73PA. The upper insulating isolation pattern 80 may include an insulating material such as silicon nitride.

The contact structure 73 may include a conductive material. The contact structure 73 may include at least one material layer. The contact structure 73 may be formed of doped polysilicon, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrOₓ, RuOₓ, graphene, carbon nanotubes, or combinations thereof, but the present inventive concepts are not limited thereto. The contact structure 73 may include a single layer or multiple layers formed of the above-described materials. For example, the contact structure 73 may include a barrier layer 75 and a contact conductive layer 77. The barrier layer 75 may cover a side surface and a lower surface of the contact conductive layer 77 in the plug portion 73PL, and may extend between the contact conductive layer 77 and the pattern structure BLS in the pad portion 73PA.

The semiconductor device 1 may further include an etch stop layer 83 and a data storage structure DS. The etch stop layer 83 may be disposed on the upper insulating isolation pattern 80 and the pad portion 73PA. The etch stop layer 83 may be formed of an insulating material.

In an example, the data storage structure DS may be a capacitor in which a DRAM stores information. For example, the data storage structure DS may be a DRAM capacitor including a first electrode 91 penetrating through the etch stop layer 83 to be electrically connected to the pad portion 73PA, a dielectric layer 93 covering the first electrode 91 and the etch stop layer 83, and a second electrode 95 on the dielectric layer 93. The dielectric layer 93 may include a high-κ dielectric, silicon oxide, silicon nitride, silicon oxynitride, or combinations thereof.

In another example, the data storage structure DS may be a structure storing information on a memory different from a DRAM. For example, the data storage structure DS may be a capacitor of a ferroelectric memory (FeRAM) including a dielectric layer 93 disposed between the first and second electrodes 91 and 95, the dielectric layer 93 including a ferroelectric layer. For example, the dielectric layer 93 may include a ferroelectric layer capable of recording data using a polarization state.

In an example embodiment, the first contact spacer structure 40 may serve as a barrier blocking or preventing an electrical short-circuit between the contact portion CP and the pad pattern PAD.

In an example embodiment, the first contact spacer structure 40 may serve to allow the contact portion CP and the first impurity region SD1 to be in stable and reliable contact with each other.

In an example embodiment, the first contact spacer structure 40 may serve as a barrier blocking or preventing an electrical short-circuit between the contact portion CP and the second impurity region SD2.

In an example embodiment, the second contact spacer structure 63 may serve as a barrier blocking or preventing an electrical short-circuit between the contact portion CP and the contact structure 73.

In an example embodiment, the second contact spacer structure 63 may serve as a barrier blocking or preventing an electrical short-circuit between the contact portion CP and the pad pattern PAD.

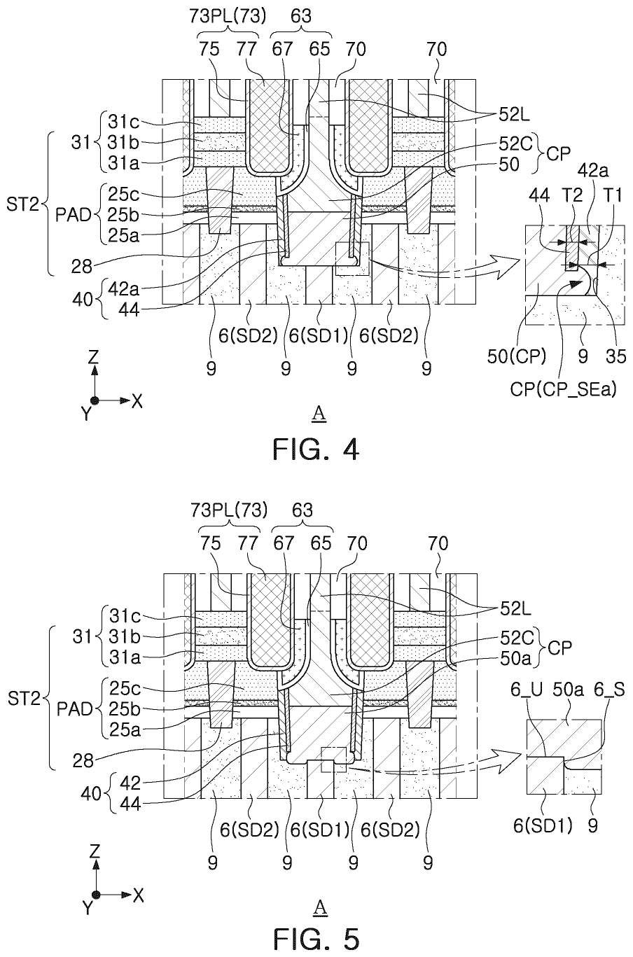

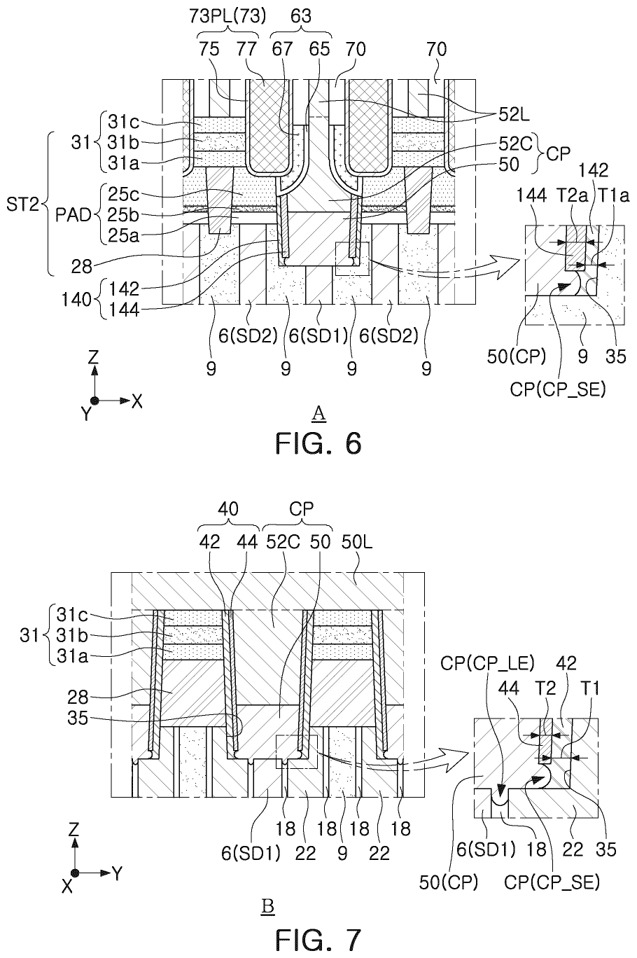

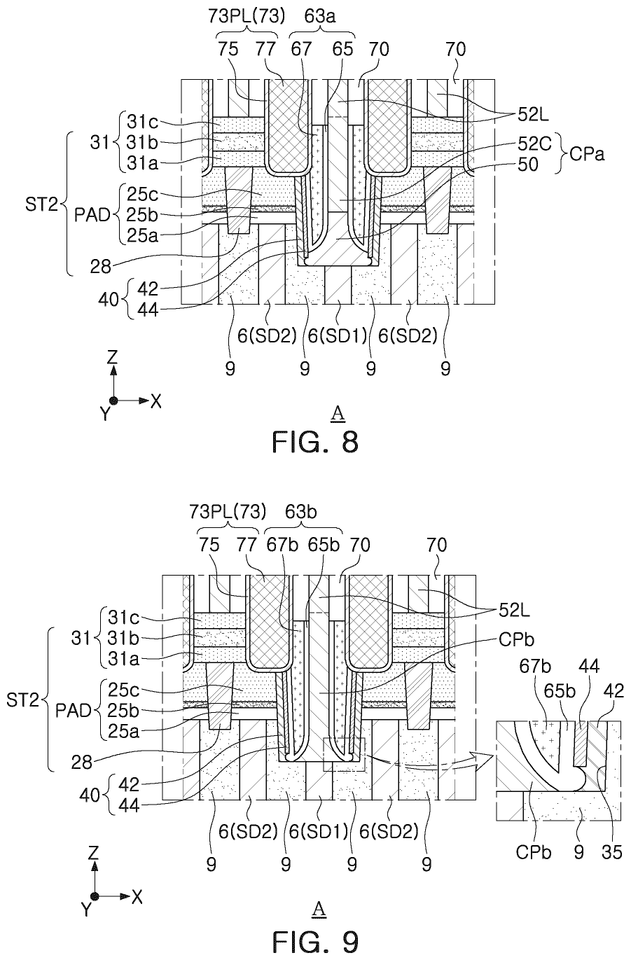

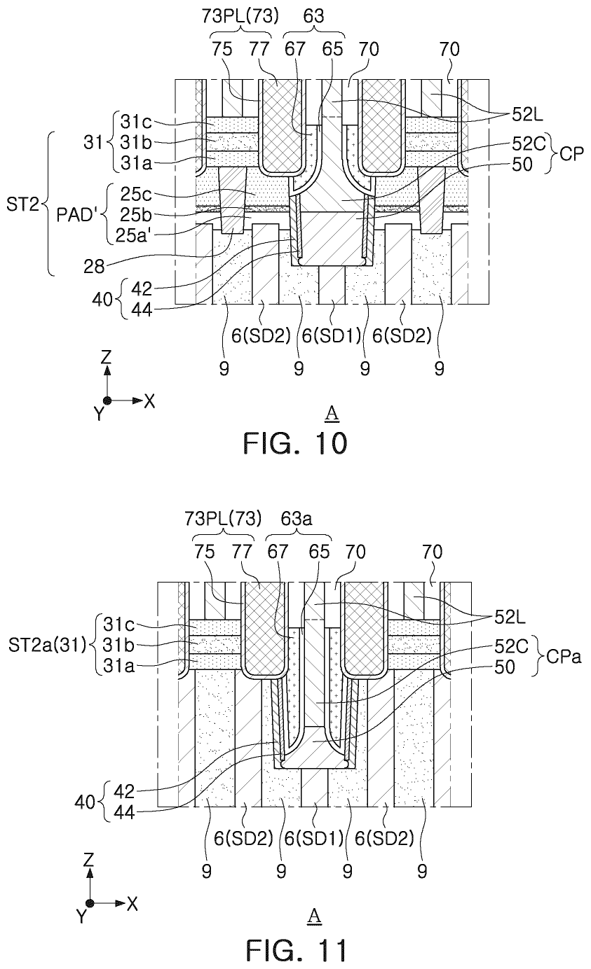

Hereinafter, various modifications of elements of the above-described semiconductor device 1 will be described with reference to FIGS. 4, 5, 6, 7, 8, 9, 10, and 11, respectively. The various modifications of the elements of the above-described semiconductor device 1 to be described below will be described based on a modified element or a replaced element. In addition, elements that can be modified or replaced are described below with reference to respective drawings. However, the elements that can be modified are combined with each other or with the above-described elements to be included in the semiconductor device 1 according to some example embodiments of the present inventive concepts. In FIGS. 4 to 11, FIG. 4 is a partially enlarged view illustrating a modification of a region indicated by “A” of FIG. 2A, FIG. 5 is a partially enlarged view of a modification of a region indicated by “A” of FIG. 2A, FIG. 6 is a partially enlarged view of a modification of a region indicated by “A” of FIG. 2A, FIG. 7 is a partially enlarged view of a modification of a region indicated by “B” of FIG. 3A, FIG. 8 is a partial enlarged view of a modification of a region indicated by “A” of FIG. 2A, FIG. 9 is a partial enlarged view of a modification of a region indicated by “A” of FIG. 2A, FIG. 10 is a partial enlarged view of a modification of a region indicated by “A” of FIG. 2A, and FIG. 11 is a partial enlarged view of a modification of a region indicated by “A” of FIG. 2A.

In a modification, referring to FIG. 4, the first extension portion CP_SE of the contact portion CP described with reference to FIGS. 2A to 3B may be modified into a first extension portion CP_ SEa extending in a direction toward a side surface of the contact opening 35. The first spacer layer 42, described with reference to FIGS. 2A and 3B, may be modified into a first spacer layer 42a having a lower region positioned at a level lower than that of the second spacer layer 44 and having a reduced horizontal thickness, by the first extension portion CP_SEa.

The first extension portion CP_SEa of the contact portion CP may vertically overlap the second spacer layer 44, and the first extension portion CP_SEa may vertically overlap at least a portion of the first spacer layer 42a.

A minimum distance between the second spacer layer 44 and a side surface of the contact opening 35 may be greater than a minimum distance between the first extension portion CP_SEa of the contact portion CP and the side surface of the contact opening 35.

In a modification, referring to FIG. 5, the contact portion CP, covering an upper surface of the first impurity region SD1, as illustrated in FIGS. 2A to 3B, may be modified into a contact portion CP, covering an upper surface 6_U of the first impurity region SD1 and an upper region 6_S of a side surface of the first impurity region SD1. For example, as illustrated in FIG. 5, the first material layer 50 of the contact portion CP may be modified into a first material layer 50a in contact with the upper surface 6_U of the first impurity region SD1 and the upper region 6_S of the side surface of the first impurity region SD1. Accordingly, a contact area between the first impurity region SD1 and the contact portion CP may be increased, thereby improving resistance properties.

In a modification, referring to FIG. 6, the first contact spacer structure 40, described with reference to FIGS. 2A to 3B, may be modified into a spacer structure 140. For example, the first spacer layer 42, described with reference to FIGS. 2A to 3B, may be replaced with a first spacer layer 142 having a reduced thickness, and the second spacer layer 44, described with reference to FIGS. 2A to 3B, may be replaced with a second spacer layer 144 having an increased thickness. Accordingly, in the spacer structure 140, a thickness T2a of the second spacer layer 144 may be greater than a thickness T1a of the first spacer layer 142. The first extension portion CP_SE of the contact portion CP, described with reference to FIGS. 2A to 3B, may vertically overlap at least a portion of a lower surface of the first spacer layer 142.

In a modification, referring to FIG. 7, the contact portion CP, described with reference to FIGS. 3A and 3B, may be in contact with an upper surface of the first impurity region SD1, exposed by the contact opening 35, a portion of the gate capping pattern 22, adjacent to the first impurity region SD1, and a portion of the gate dielectric layer 18. Here, the contact portion CP, described with reference to FIGS. 3A and 3B, may further include a second extension portion CP_LE extending in a direction toward the gate dielectric layer 18, vertically overlapping the contact portion CP, to be in contact with the gate dielectric layer 18. The second extension portion CP_LE may extend between the first impurity region SD1, vertically overlapping the contact portion CP, and the gate capping pattern 22. Accordingly, below the contact portion CP, an upper end of the gate dielectric layer 18 in contact with the contact portion CP may be disposed at a level lower than that of an upper surface of the first impurity region SD1 and an upper surface of the gate capping pattern 22.

In a modification, referring to FIG. 8, the second contact spacer structure 63 having a lower end positioned at a level higher than that of a lower surface of the pad pattern PAD, as described with reference to FIGS. 2A and 2B, may extend downwardly to be modified into a second contact spacer structure 63a having a lower end positioned at a level lower than that of the lower surface of the pad pattern PAD. The contact portion CP, described with reference to FIGS. 2A and 2B, may be modified into a contact portion CPa having a reduced width, by the second contact spacer structure 63a. For example, the second contact spacer structure 63a may be disposed between the first contact spacer structure 40 and the contact portion CPa, a lower end of the second contact spacer structure 63a may be disposed at a level lower than that of a lower surface of the pad pattern PAD, and an upper end of the second contact spacer structure 63a may be between an upper surface of the contact portion CPa and a lower end of the second spacer layer 44.

In a modification, referring to FIG. 9, the second contact spacer structure 63 having a lower end positioned at a level higher than that of a lower surface of the pad pattern PAD, as described with reference to FIGS. 2A and 2B, may be modified into a second contact spacer structure 63b extending downwardly to extend to a bottom surface of the contact opening 35. The contact portion CP, described with reference to FIGS. 2A and 2B, may be modified into the contact portion CPb having a reduced width and spaced apart from the first contact spacer structure 40 by the second contact spacer structure 63b. For example, the second contact spacer structure 63b may be disposed between the first contact spacer structure 40 and the contact portion CPb, and may be in contact with the bottom surface of the contact opening 35.

The second contact spacer structure 63b may include an insulating liner 65b and a spacer pattern 67b respectively corresponding to the insulating liner 65 and the spacer pattern 67, described with reference to FIGS. 2A and 2B.

The contact portion CPb may be spaced apart from the first contact spacer structure 40 by the second contact spacer structure 63b, and a portion of the second contact spacer structure 63b may extend between the second spacer layer 44 and the bottom surface of the contact opening 35, and may be in contact with the first spacer layer 42. For example, the insulating liner 65b of the second contact spacer structure 63b may extend between the second spacer layer 44 and the bottom surface of the contact opening 35, and may be in contact with the first spacer layer 42.

In a modification, referring to FIG. 10, the pad pattern PAD in contact with an upper surface of the second impurity region SD2, described with reference to FIGS. 2A and 2B, may be modified into a pad pattern PAD' in contact with the upper surface of the second impurity region SD2 and an upper region of a side surface of the second impurity region SD2. For example, among the first to third pad layers 25a, 25b, and 25c described with reference to FIG. 2B, the first pad layer (25a in FIG. 2B) may be modified into a first pad layer 25a′ in contact with the upper surface of the second impurity region SD2 and the upper region of the side surface of the second impurity region SD2. Accordingly, a contact area between the pad pattern PAD' and the second impurity region SD2 may be increased, thereby improving resistance properties.

In a modification, referring to FIG. 11, the second structure ST2 including the pad pattern PAD, the insulating isolation pattern 28, and the insulating buffer pattern 31, described with reference to FIGS. 2A to 3B, may be modified into a second structure ST2a including the second insulating buffer pattern 31 and not including the pad pattern PAD and the insulating isolation pattern 28. Accordingly, the second insulating buffer pattern 31 of the second structure ST2a may directly cover the isolation region 9 while being in contact with the isolation region 9, and the contact structure 73 may be electrically connected to the second impurity region SD2 while being in direct contact with the second impurity region SD2. The contact opening 35 may pass through the second structure ST2a and extend into the first structure ST1 to expose the first impurity region SD1. A shape and structure of a structure disposed in the contact opening 35 may be the same as or substantially similar to those in one of the example embodiment of FIG. 2B, the example embodiment of FIG. 4, the example embodiment of FIG. 5, the example embodiment of FIG. 6, and the example embodiment of FIG. 8. For example, FIG. 11 illustrates the contact portion CPa and the second contact spacer structure 63a described with reference to FIG. 8, but example embodiments are not limited thereto.

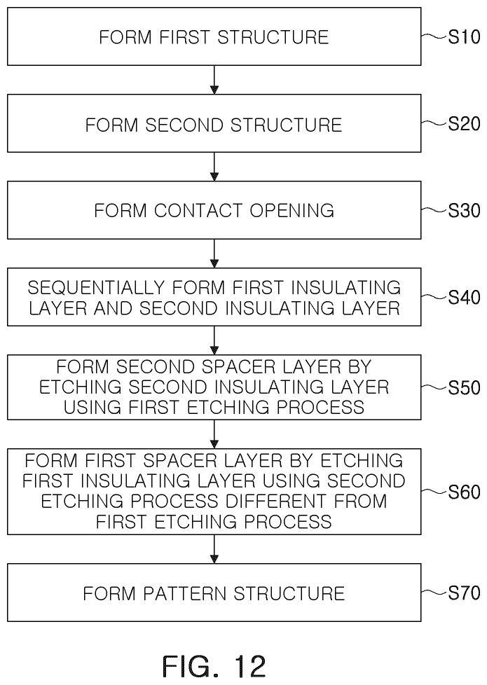

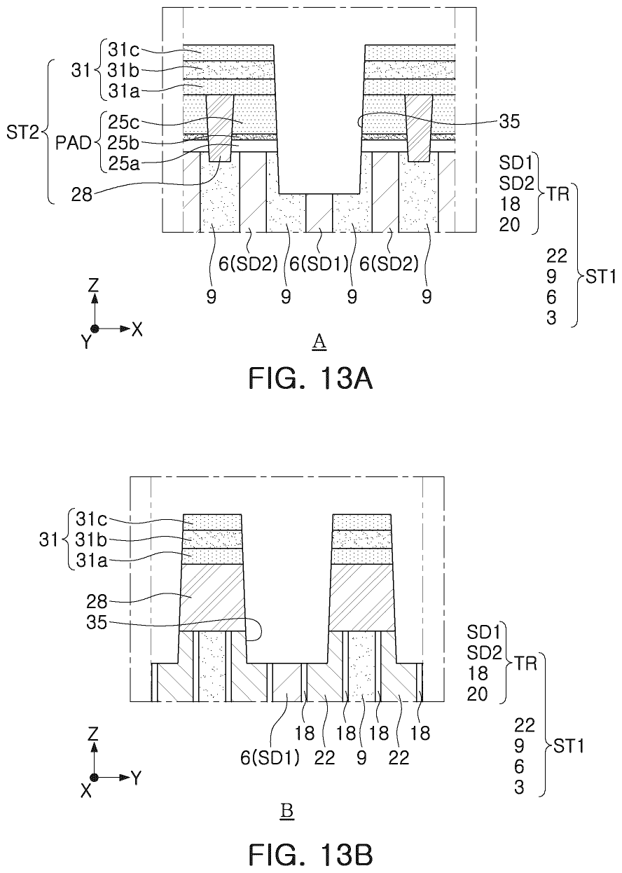

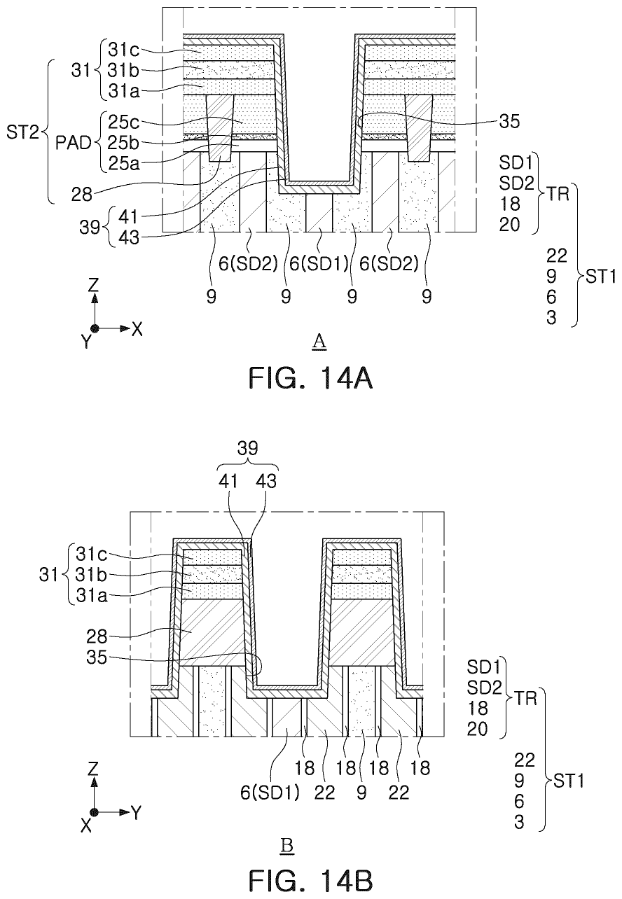

Subsequently, a method of forming a semiconductor device according to an example embodiment of the present inventive concepts will be described with reference to FIGS. 12 and 13A to 16B. In FIGS. 12 and 13A to 16B, FIG. 12 is a process flowchart illustrating a method of forming a semiconductor device according to an example embodiment of the present inventive concepts, FIGS. 13A, 14A, 15A, and 16A are partially enlarged views of a region corresponding to a region indicated by “A” of FIG. 2A, and FIGS. 13B, 14B, 15B, and 16B are partially enlarged views of a region corresponding to a region indicated by “B” of FIG. 3A.

Referring to FIGS. 12, 13A, and 13B, a first structure ST1 may be formed (S10). The first structure ST1 may include the substrate 3, the active regions 6, the isolation region 9, the first impurity region SD1, the second impurity regions SD2, and the gate structure (GS in FIGS. 1 and 3A), as described with reference to FIGS. 1 and 2A to 3B. As described with reference to FIGS. 1 and 2A to 3B, the first and second impurity regions SD1 and SD2 may be disposed in upper regions of the active regions 6, and the gate structure GS may include the gate dielectric layer 18, the gate electrode 20, and the gate capping pattern 22. An upper surface of the first structure ST1 may be flat.

A second structure ST2 may be formed (S20). One or more pad layers 25a, 25b, and 25c may be formed on the first structure ST1. An insulating isolation pattern 28, penetrating through the one or more the pad layers 25a, 25b, and 25c, may be formed. One or more buffer layers 31a, 31b, and 31c may be formed on the insulating isolation pattern 28 and the one or more pad layers 25a, 25b, and 25c.

The one or more pad layers 25a, 25b, and 25c may include a first pad layer 25a, a second pad layer 25b, and a third pad layer 25c sequentially stacked. The first pad layer 25a may include doped silicon, the second pad layer 25b may include TiSiN or a metal-semiconductor compound, and the third pad layer 25c may include a metal such as W or the like. The one or more buffer layers 31a, 31b, and 31c may include a first buffer layer 31a, a second buffer layer 31b, and a third buffer layer 31c sequentially stacked. The first buffer layer 31a may include silicon nitride, the second buffer layer 31b may include silicon oxide, and the third buffer layer 31c may include silicon nitride.

A contact opening 35 may be formed (S30). The contact opening 35 may pass through the one or more buffer layers 31a, 31b, and 31c, the insulating isolation pattern 28, and the one or more pad layers 25a, 25b, and 25c, and may expose at least the first impurity region SD1. Here, the one or more pad layers 25a, 25b, and 25c, remaining after the contact opening 35 is formed, may be formed as a pad pattern PAD, and the one or more buffer layers 31a, 31b, and 31c, remaining after the contact opening 35 is formed, may be formed as an insulating buffer pattern 31. The pad pattern PAD may be electrically connected to the second impurity region SD2 while being in contact with the second impurity region SD2. The insulating buffer pattern 31, the pad pattern PAD, and the insulating isolation pattern 28 may be included in the second structure ST2. An upper surface of the first impurity region SD1 may be lowered by the contact opening 35. Accordingly, the upper surface of the first impurity region SD1 may be formed at a level lower than that of an upper surface of the second impurity region SD2.

The contact opening 35 may expose a portion of the isolation region 9 and a portion of the gate structure GS, adjacent to the first impurity region SD1. For example, the contact opening 35 may expose the gate capping pattern 22 of the gate structure GS.

Referring to FIGS. 12, 14A and 14B, a first insulating layer 41 and a second insulating layer 43 may be sequentially formed (S40). The first and second insulating layers 41 and 43 may be included in a spacer layer 39.

The first insulating layer 41 may cover an upper surface of the insulating buffer pattern 31 while conformally covering a side surface and a bottom surface of the contact opening 35. The second insulating layer 43 may conformally cover the first insulating layer 41.

The first and second insulating layers 41 and 43 may be formed of different insulating materials. The first and second insulating layers 41 and 43 may be formed of insulating materials having etch selectivity with respect to each other. For example, the first insulating layer 41 may be an oxide layer, and the second insulating layer 43 may be a SiOC material layer. The first insulating layer 41 may include silicon oxide, but example embodiments are not limited thereto. For example, when the second insulating layer 43 is formed as a SiOC material layer, the first insulating layer 41 may be formed of silicon oxide, a low-κ dielectric, or a high-κ dielectric.

In an example, a thickness of the first insulating layer 41 may be greater than that of the second insulating layer 43.

In another example, the thickness of the first insulating layer 41 may be equal to or substantially similar to that of the second insulating layer 43.

In another example, in order to form the first and second spacer layers 142 and 144 described with reference to FIG. 6, the thickness of the first insulating layer 41 may be less than that of the second insulating layer 43.

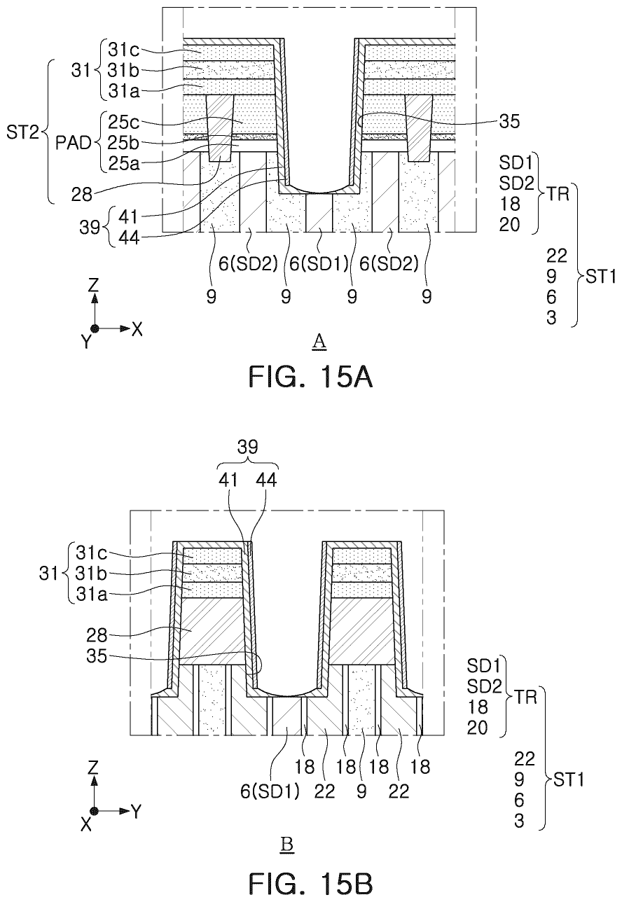

Referring to FIGS. 12, 15A and 15B, a second spacer layer 44 may be formed by etching the second insulating layer 43 in FIGS. 14A and 14B using a first etching process (S50). The second spacer layer 44 may be formed on a side surface of the contact opening 35. The first etching process may be a dry etching process capable of etching the second insulating layer 43 in FIGS. 14A and 14B. For example, the first etching process may be a plasma etching process capable of performing anisotropic etching.

The first insulating layer 41 may block or prevent a surface of the first impurity region SD1 from being damaged by the first etching process for etching the second insulating layer 43 in FIGS. 14A and 14B. A portion of the first insulating layer 41 on the first impurity region SD1 may be etched by the first etching process, but the first insulating layer 41 may protect an upper surface of the first impurity region SD1 from the first etching process.

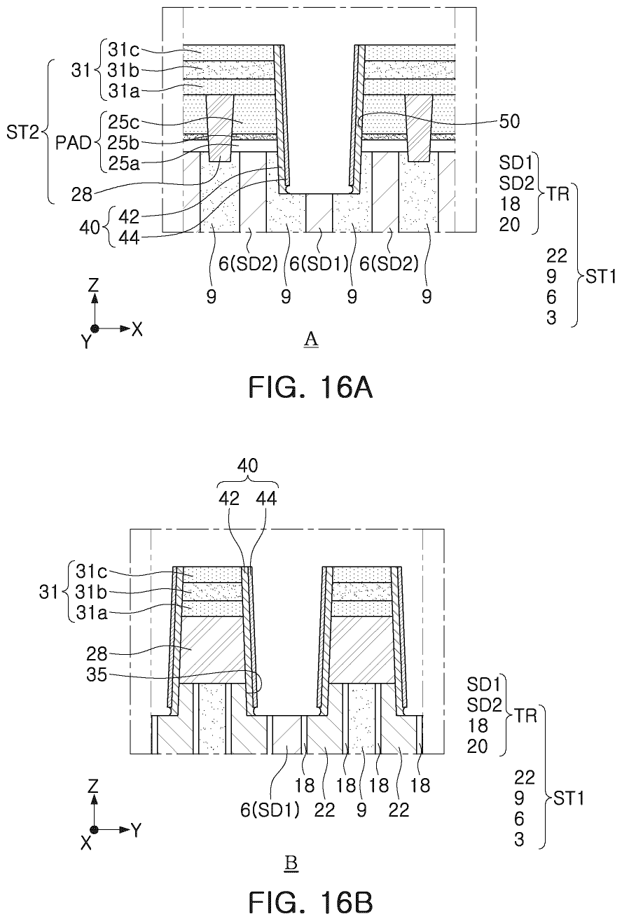

Referring to FIGS. 12, 16A and 16B, the first insulating layer (41 in FIGS. 15A and 15B) may be etched by a second etching process different from the first etching process to form a first spacer layer 42 (S60). The second etching process may selectively etch the first insulating layer 41 in FIGS. 15A and 15B. The second etching process may be a wet etching process capable of preventing or minimizing surface damage of the first impurity region SD1. The second etching process may be an isotropic etching process.

The first spacer layer 42 and the second spacer layer 44 may be included in a first contact spacer structure 40. Accordingly, the first contact spacer structure 40 may be formed as described with reference to FIGS. 1 and 2A to 3B. A shape and structure of the first contact spacer structure 40 have been described with reference to FIGS. 1 and 2A to 3B, and thus a detailed description thereof will be omitted herein.

When the first insulating layer 41 in FIGS. 15A and 15B is over-etched by the second etching process, the first spacer layer 42 may be formed as the first spacer layer 42a, as illustrated in FIG. 4.

When a portion of the isolation region 9 is etched by the second etching process, the upper surface 6_U and the upper region 6_S of the side surface of the first impurity region SD1 may be exposed by the contact opening 35, as illustrated in FIG. 5.

When a portion of the gate dielectric layer 18, exposed by the contact opening 35, is etched by the second etching process, an upper end of the gate dielectric layer 18, positioned between the first impurity region SD1 and the gate capping pattern 22, may be lowered, as illustrated in FIG. 7.

Referring to FIGS. 1, 2A, 2B, 3A, and 3B together with FIG. 12, a pattern structure BLS may be formed (S70).

The pattern structure BLS may include a contact portion CP in the contact opening 35, a line portion BL on the contact portion CP and the second structure ST2, and an insulating capping portion 58 on the line portion BL.

Forming the pattern structure BLS may include forming at least one material layer covering the second structure ST2 while filling the contact opening 35 having a sidewall covered by the first contact spacer structure 40, forming an insulating capping portion 58 on the at least one material layer, forming the line portion BL by etching at least one material layer on the second structure ST2 via an etching process using the insulating capping portion 58 as an etching mask, and etching at least a portion of the at least one material layer in the contact opening 35 via the etching process. Here, the at least one material layer remaining in the contact opening 35 may be defined as the contact portion CP.

In an example, forming the at least one material layer covering the second structure ST2 while filling the contact opening 35 having a sidewall covered by the first contact spacer structure 40 may include forming a first material layer 50 partially filling the contact opening 35 by performing an epitaxial growth process, and forming one or more conductive layers 52C, 52L, 54, and 56 on the first material layer 50. The first material layer 50 may be formed as an epitaxial silicon layer by the epitaxial growth process, but example embodiments are not limited thereto. For example, the first material layer 50 may be formed of polysilicon.

A second contact spacer structure 63, filling a remaining portion of the contact opening 35, may formed on a side surface of the pattern structure BLS, and a line spacer 70 may be formed on the line portion BL of the pattern structure BLS and a side surface of the insulating capping portion 58.

An insulating layer, filling a space between the pattern structures BLS, may be formed on the second structure ST2, a contact hole, exposing the pad pattern PAD while penetrating through the insulating layer and the insulating buffer pattern 31, may be formed, and one or more conductive layers, covering the pattern structures BLS while filling the contact hole, may be formed. An upper insulating isolation pattern 80, allowing the one or more conductive layers to be spaced apart from each other while penetrating through the one or more conductive layers positioned at a level higher than that of the pattern structures BLS, may be formed. The one or more conductive layers may be formed as contact structures 73 by the upper insulating isolation pattern 80. One contact structure 73 may be electrically connected to the pad pattern PAD while being in contact with the pad pattern PAD.

An etch stop layer 83, covering the contact structure 73 and the upper insulating isolation pattern 80, may be formed, and a data storage structure DS, electrically connected to the contact structure 73, may be formed. The data storage structure DS may include a first electrode 91 electrically connected to the contact structure 73 while penetrating through the etch stop layer 83, a dielectric layer 93 covering the first electrode 91, and a second electrode 95 covering the dielectric layer 93.

In some example embodiments, the first contact spacer structure 40, including the first and second spacer layers 42 and 44, may serve to allow the contact portion CP and the first impurity region SD1 to be in stable and reliable contact with each other. For example, the above-described first insulating layer (41 in FIGS. 14A and 14B) and the second insulating layer (43 in FIGS. 14A and 14B) may be formed of materials having etch selectivity, and a surface of the first impurity region SD1 may be exposed without damage during the first etching process (S50 in FIG. 12) and the second etching process (S60 in FIG. 12) for etching the first and second insulating layers 41 and 43 performed to form the first and second spacer layers 42 and 44. Accordingly, the contact portion CP may be formed on the first impurity region SD1 capable of preventing or minimizing surface damage, such that the contact portion CP and the first impurity region SD1 may be in stable and reliable contact with each other. Accordingly, according to some example embodiments, reliable semiconductor devices 1 may be provided.

According to some example embodiments, there may be provided a method of forming a second spacer layer by forming a contact opening exposing an impurity region, forming a first insulating layer covering a side surface and a bottom surface of the contact opening, forming a second insulating layer on the first insulating layer, and anisotropically etching the second insulating layer using a dry etching process, while forming a first spacer layer by exposing the first insulating layer, and etching the first insulating layer using a wet etching process in which the impurity region is not damaged by etching. Thus, a contact spacer structure including the first and second spacer layers may be provided.

According to some example embodiments, a contact spacer structure, covering a side surface of the contact opening, may be provided to have a spacer structure in which a surface of the impurity region exposed by the contact opening is not damaged.

According to some example embodiments, a patterned structure including a contact portion disposed in the contact opening and connected to the impurity region while being in contact with the impurity region. The contact spacer structure may serve to block or prevent an electrical short-circuit between the contact portion and another conductive region, adjacent to the contact portion, for example, a pad pattern and the impurity region.

The contact spacer structure according to some example embodiments may serve to block or prevent a defect occurring between the contact portion and the other conductive region, and may serve to allow the contact portion and the impurity region to be in stable and reliable contact with each other. Thus, a reliable semiconductor device may be provided.

The various and beneficial advantages and effects of the present inventive concepts are not limited to those set forth herein, and will be more easily understood in the course of describing specific example embodiments.

While some example embodiments have been illustrated and described above, it will be apparent to those skilled in the art that modifications and variations could be made without departing from the scope of the present inventive concepts as defined by the appended claims.

What is claimed is:

1. A semiconductor device comprising:
a first structure including a first impurity region, a second impurity region, and an isolation region;
a second structure on the first structure, the second structure including a contact opening penetrating therethrough and exposing the first impurity region;
a pattern structure including a contact portion connected to the first impurity region in the contact opening, and a line portion on the contact portion and the second structure; and
a spacer structure between a side surface of the contact opening and the contact portion,
wherein the spacer structure includes,
a first spacer layer on the side surface of the contact opening, and
a second spacer layer between the first spacer layer and the contact portion,
wherein a lower end of the second spacer layer is at a higher level than a lower surface of the contact portion, and
wherein the contact portion includes,
a first contact region connected to the first impurity region, and
a first extension portion protruding from the first contact region and extending between the lower surface of the second spacer layer and a bottom surface of the contact opening.

2. The semiconductor device of claim 1, wherein
the second spacer layer has a first side surface opposing the side surface of the contact opening and a second side surface opposing the first side surface,
the first side surface of the second spacer layer is in contact with the first spacer layer, and
the contact portion is in contact with the second side surface of the second spacer layer and the lower surface of the second spacer layer.

3. The semiconductor device of claim 1, wherein
the second spacer layer has a first side surface opposing the side surface of the contact opening and a second side surface opposing the first side surface,
the contact portion is in contact with the second side surface of the second spacer layer and the lower surface of the second spacer layer, and
the first extension portion extends in a direction toward the side surface of the contact opening to vertically overlap at least a portion of the first spacer layer.

4. The semiconductor device of claim 1, wherein
the first structure further includes a gate structure, the gate structure including
a gate electrode extending in a first horizontal direction,
a gate capping pattern on the gate electrode, and
a gate dielectric layer covering a side surface of the gate electrode and a side surface of the gate capping pattern,
the first impurity region is adjacent to the gate capping pattern, and
a portion of the gate dielectric layer is between the first impurity region and the gate capping pattern.

5. The semiconductor device of claim 4, wherein
the gate capping pattern includes,
a first capping region vertically overlapping the contact portion, and
a second capping region vertically overlapping the second structure,
an upper surface of the second capping region of the gate capping pattern is at a higher level than an upper surface of the first capping region of the gate capping pattern, and
the contact portion covers an upper surface of the first impurity region and an upper surface of the first capping region of the gate capping pattern.

6. The semiconductor device of claim 4, wherein the contact portion further includes a second extension portion extending between the first impurity region and the gate capping pattern and being in contact with the gate dielectric layer.

7. The semiconductor device of claim 1, wherein
the isolation region includes,
a first isolation region vertically overlapping the contact portion, and
a second isolation region vertically overlapping the second structure,
an upper surface of the second isolation region is at a higher level than an upper surface of the first isolation region, and
the contact portion covers an upper surface of the first impurity region and an upper surface of the first isolation region.

8. The semiconductor device of claim 7, wherein the upper surface of the first isolation region and the upper surface of the first impurity region are coplanar with each other.

9. The semiconductor device of claim 7, wherein the contact portion covers the upper surface of the first impurity region and an upper region of a side surface of the first impurity region.

10. The semiconductor device of claim 1, wherein
the second structure includes,
a pad pattern connected to the second impurity region,
an insulating isolation pattern on a side surface of the pad pattern, and
an insulating buffer pattern on the pad pattern and the insulating isolation pattern, and
the pad pattern includes at least one conductive layer.

11. The semiconductor device of claim 10, wherein
the pattern structure further includes an insulating capping pattern on the line portion,
the pattern structure includes,
a doped silicon layer connected to the first impurity region, and
at least one conductive layer on the doped silicon layer, and
the doped silicon layer and the at least one conductive layer of the pattern structure are included in the contact portion and the line portion.

12. The semiconductor device of claim 10, further comprising:
a line spacer on a side surface of the line portion;
a contact spacer structure below the line spacer and on at least a portion of a side surface of the contact portion in the contact opening;
a contact structure electrically connected to the pad pattern; and
a data storage structure on the contact structure and electrically connected to the contact structure and,
wherein the contact structure includes a pad portion vertically overlapping at least a portion of an upper surface of the pattern structure and on a level higher than that of the upper surface of the pattern structure.

13. A semiconductor device comprising:
a first structure including a first impurity region, a second impurity region, and an isolation region;
a second structure including a pad pattern connected to the second impurity region, an insulating isolation pattern having a side surface in contact with a side surface of the pad pattern, and an insulating buffer pattern on the pad pattern and the insulating isolation pattern, the second structure including a contact opening penetrating therethrough and exposing an upper surface of the first impurity region and a first portion of the isolation region;
a pattern structure including a contact portion in the contact opening and a line portion on the contact portion and the second structure;
a contact spacer structure between a side boundary of the contact opening defined by the second structure and the contact portion; and
a contact structure connected to an upper surface of the pad pattern, the contact structure extending upwardly,
wherein the contact spacer structure includes,
a first spacer layer on the side boundary of the contact opening, and
a second spacer layer between the first spacer layer and the contact portion,
wherein the second spacer layer has a first side surface in contact with the first spacer layer and a second side surface opposing the first side surface,
wherein a lower end of the second spacer layer is at a higher level than a lower end of the first spacer layer, and
wherein a lower end of the second side surface of the second spacer layer does not vertically overlap the first spacer layer.

14. The semiconductor device of claim 13, wherein the contact spacer structure has a ring shape in plan view.

15. The semiconductor device of claim 13, wherein a thickness of the first spacer layer is greater than a thickness of the second spacer layer.

16. The semiconductor device of claim 13, wherein
the pad pattern covers the second impurity region and a second portion of the isolation region, adjacent to the second impurity region,
the isolation region includes,
a first isolation region vertically overlapping the contact portion, and
a second isolation region vertically overlapping the pad pattern,
an upper surface of the second isolation region is at a higher level than an upper surface of the first isolation region,
wherein the contact spacer structure includes:
a first spacer region not vertically overlapping the line portion; and
a second spacer region vertically overlapping the line portion,
wherein the first spacer region is in contact with a side surface of the pad pattern and a portion of a side surface of the isolation region below the pad pattern, and
wherein the second spacer region is in contact with a side surface of the insulating isolation pattern and a side surface of the insulating buffer pattern.

17. A semiconductor device comprising:
a first structure;
a second structure on the first structure, the second structure including a contact opening penetrating therethrough;
a pattern structure including a contact portion in the contact opening, and a line portion on the contact portion and the second structure; and
a contact spacer structure between a side boundary of the contact opening defined by the second structure and the contact portion,
wherein the first structure includes,
a substrate,
a first active region and a second active region on the substrate,
an isolation region on side surfaces of the first and second active regions,
a first impurity region in an upper region of the first active region and a second impurity region in an upper region of the second active region,
a gate trench traversing the first and second active regions and extending into the isolation region, and
a gate structure in the gate trench,
wherein the gate structure includes
a gate dielectric layer covering an inner wall of the gate trench,
a gate electrode partially filling the gate trench on the gate dielectric layer; and
a gate capping pattern on the gate electrode in the gate trench,
wherein the gate electrode has a linear shape extending in a first horizontal direction,
wherein the line portion has a linear shape extending in a second horizontal direction, perpendicular to the first horizontal direction,
wherein the second structure includes,
a pad pattern connected to the second active region,
an insulating isolation pattern in contact with side surfaces of the pad pattern, and
an insulating buffer pattern on the pad pattern and the insulating isolation pattern,
wherein the contact opening exposes the first impurity region, the isolation region adjacent to the first impurity region, and the gate capping pattern adjacent to the first impurity region,
wherein the contact spacer structure includes a first spacer layer on the side boundary of the contact opening and a second spacer layer between the first spacer layer and the contact portion,
wherein a material of the first spacer layer is different from a material of the second spacer layer,
wherein a lower end of the first spacer layer is at a lower level than a lower end of the second spacer layer, and
wherein each of the first and second spacer layers has a ring shape in plan view.

18. The semiconductor device of claim 17, wherein in a cross-sectional structure in which the contact portion and the line portion are cut in the first horizontal direction,
the contact spacer structure is in contact with both a side surface of the pad pattern and a side surface of the contact portion that is between the pad pattern and the contact portion.

19. The semiconductor device of claim 17, wherein in a cross-sectional structure in which the contact portion and the line portion are cut in the second horizontal direction,
the contact spacer structure is in contact with both a side surface of the second structure and a side surface of the contact portion, and
the side surface of the second structure is a side surface of the insulating isolation pattern and a side surface of the insulating buffer pattern.

20. The semiconductor device of claim 19, wherein the contact portion includes an extension portion extending between a bottom surface of the contact opening and a lower surface of the second spacer layer.
